(19) United States
(12) Patent Application Publication
(10) Pub. No.: US 2023/0204414 A1
(43) Pub. Date: Jun. 29, 2023

(54) DETECTING UNIT AND SUBSTRATE TREATING APPARATUS INCLUDING THE SAME

(71) Applicant: SEMES CO., LTD., Cheonan-si (KR)

(72) Inventors: Hyun YOON, Hwaseong-si (KR); Ki Hoon CHOI, Cheonan-si (KR); Tae Hee KIM, Yongin-si (KR); Ji Hoon JEONG, Hwaseong-si (KR)

(21) Appl. No.: 17/979,149

(22) Filed: Nov. 2, 2022

(30) Foreign Application Priority Data
Dec. 28, 2021 (KR) 10-2021--0189865

(51) Int. Cl. G01J 1/42; G01J 1/02; G03F 7/20

(52) U.S. Cl. CPC G01J 1/4257; G01J 1/0271; G03F 7/2053

(57) ABSTRACT

The present invention provides a substrate treating apparatus including: support unit is configured to support and rotate a substrate in a treatment space; a liquid supply unit is configured to supply a liquid to the substrate supported by the support unit; a laser unit including a laser irradiation unit which irradiates laser light to the substrate supported by the support unit; a home port providing a standby position in which the laser unit waits; and a moving unit for moving the laser unit between a process position in which the laser light is irradiated to the substrate and the standby position, in which the home port detects a characteristic of the laser light from the laser light irradiated by the laser unit.

### CROSS-REFERENCE TO RELATED APPLICATIONS

This application claims priority to and the benefit of Korean Patent Application No. 10-2021-0189865 filed in the Korean Intellectual Property Office on Dec. 28, 2021, the entire contents of which are incorporated herein by reference.

### TECHNICAL FIELD

The present invention relates to a detecting unit and a substrate treating apparatus including the same, and more particularly, to a detecting unit for detecting a characteristic of light and a substrate treating apparatus including the same.

### BACKGROUND ART

A photography process for forming a pattern on a wafer includes an exposure process. The exposure process is a preliminary operation for scraping a semiconductor integrated material adhered on the wafer into a desired pattern. The exposure process may have various purposes, such as forming a pattern for etching and forming a pattern for ion implantation. In the exposure process, a pattern is drawn with light on the wafer by using a mask, which is a kind of ‘frame’. When the semiconductor integrated material on a wafer, for example, a resist on the wafer, is exposed to light, chemical properties of the resist are changed according to a pattern by the light and the mask. When a developer is supplied to the resist whose chemical properties are changed according to the pattern, a pattern is formed on the wafer.

In order to precisely perform the exposure process, the pattern formed on the mask needs to be precisely manufactured. Whether the pattern is formed satisfactorily under the required process conditions needs to be checked. A large number of patterns are formed on one mask. Accordingly, it takes a lot of time for an operator to inspect all of a large number of patterns in order to inspect one mask. Accordingly, a monitoring pattern that may represent one pattern group including a plurality of patterns is formed on the mask. In addition, an anchor pattern that may represent a plurality of pattern groups is formed on the mask. The operator may estimate the quality of the patterns included in one pattern group through the inspection of the monitoring pattern. In addition, the operator may estimate the quality of the patterns formed on the mask through the inspection of the anchor pattern.

In addition, in order to increase the inspection accuracy of the mask, it is preferable that the critical dimensions of the monitoring pattern and the anchor pattern are the same. A critical dimension correction process for precisely correcting the line widths of the patterns formed on the mask is additionally performed.

FIG. 1 shows a normal distribution with respect to a first critical dimension CDP1 of a monitoring pattern and a second critical dimension CDP2 of an anchor pattern of a mask before a critical dimension correction process is performed during a mask manufacturing process. In addition, the first critical dimension CDP1 and the second critical dimension CDP2 have sizes smaller than a target critical dimension. Before the critical dimension correction process is performed, there is a deliberate deviation in the Critical Dimensions (CDs) of the monitoring pattern and the anchor pattern. Then, by additionally etching the anchor pattern in the critical dimension correction process, the critical dimensions of the two patterns are made the same. When the anchor pattern is over-etched than the monitoring pattern in the process of additionally etching the anchor pattern, the critical dimension of the patterns formed on the mask cannot be precisely corrected due to the difference in the critical dimension between the monitoring pattern and the anchor pattern. When the anchor pattern is additionally etched, precise etching of the anchor pattern needs to be accompanied.

In order for the anchor pattern to be precisely etched, the focal distribution (profile) and light power of light indicating information, such as the diameter of the light and the intensity of light, need be precisely controlled. The focal distribution of light and the power value of light have a great influence on the etching amount for the pattern formed on the substrate M and the etching uniformity with respect to the pattern formed on the substrate M. In general, an attenuation filter that transmits only light of a specific wavelength band or blocks light of a specific wavelength band is installed in order to measure the light profile. For the light passing through the attenuation filter, only the relative power value may be estimated, and the absolute light power value cannot be measured, so the measurement accuracy is lowered. If the light profile and light power are not accurately measured, the anchor pattern cannot be accurately etched.

### SUMMARY OF THE INVENTION

The present invention has been made in an effort to provide a detecting unit capable of performing precise etching on a substrate and a substrate treating apparatus including the same.

The present invention has also been made in an effort to provide a detecting unit capable of detecting characteristics of light in a home port and a substrate treating apparatus including the same.

The present invention has also been made in an effort to provide a detecting unit capable of simultaneously measuring a light and light power from light irradiated from a home port, and a substrate treating apparatus including the same.

The present invention has also been made in an effort to provide a detecting unit capable of accurately measuring characteristics of light, and a substrate treating apparatus including the same.

The present invention has also been made in an effort to provide a detecting unit capable of minimizing measurement interference of a light profile due to refracted or scattered light, and a substrate treating apparatus including the same.

The problem to be solved by the present invention is not limited to the above-mentioned problems, and the problems not mentioned will be clearly understood by those skilled in the art from the present specification and the accompanying drawings.

An exemplary embodiment of the present invention provides a substrate treating apparatus including: support unit is configured to support and rotate a substrate in a treatment space; a liquid supply unit is configured to supply a liquid to the substrate supported by the support unit; a laser unit including a laser irradiation unit which irradiates laser light to the substrate supported by the support unit; a home port providing a standby position in which the laser unit waits; and a moving unit for moving the laser unit between a process position in which the laser light is irradiated to the substrate and the standby position, in which the home port detects a characteristic of the laser light from the laser light irradiated by the laser unit.

According to the exemplary embodiment, the characteristic of the laser light may include a focal distribution of the laser light and power of the laser light.

According to the exemplary embodiment, the home port may include: a housing having an inner space; a profile measuring member installed in the housing and measuring the focal distribution of the laser light; a power measuring member installed in the housing and measuring the power of the laser light; and a light splitting member for splitting the laser light incident from an upper portion of the housing to the profile measuring member and the power measuring member.

According to the exemplary embodiment, a surface of the light splitting member facing the power measuring member may be anti-reflectively coated.

According to the exemplary embodiment, the profile measuring member may be installed on a side wall of the housing, the power measuring member may be installed on a bottom wall of the housing, the light splitting member may be disposed in the inner space of the housing, an upper surface of the light splitting member may be formed to be inclined upwardly at a first angle with respect to the ground, and a lower surface of the light splitting member may be formed to be inclined upwardly at a second angle with respect to the ground, and the second angle may be greater than the first angle.

According to the exemplary embodiment, a part of the laser light incident from the upper portion of the housing may be reflected from the upper surface and be incident to the profile measuring member, another part of the laser light incident from the upper portion of the housing may be refracted on the upper surface and be incident on the lower surface, and the laser light incident on the lower surface may be incident to the power measuring member.

According to the exemplary embodiment, a part of the laser light incident to the power measuring member may be reflected and incident to the light splitting member, and the laser light incident to the light splitting member may be refracted.

According to the exemplary embodiment, the substrate treating apparatus may further include a lifting member installed at a lower end of the home port to move the housing.

According to the exemplary embodiment, the profile measuring member may further include an optical filter for filtering a specific wavelength of the laser light.

Another exemplary embodiment of the present invention provides a detecting unit for detecting a characteristic of light irradiated to a substrate, the detecting unit including: a housing having an inner space; a profile measuring member installed in the housing and measuring a focal distribution of the laser light among characteristics of the laser light; a power measuring member installed in the housing and measuring power of the laser light among the characteristics of the laser light; and a light splitting member for splitting the laser light incident from an upper portion of the housing to the profile measuring member and the power measuring member.

According to the exemplary embodiment, the profile measuring member may be installed on a side wall of the housing, the power measuring member may be installed on a bottom wall of the housing, the light splitting member may be disposed in the inner space of the housing, and a surface of the light splitting member facing the power measuring member may be anti-reflectively coated.

According to the exemplary embodiment, the light splitting member may have an upper surface and a lower surface each of which is formed to be inclined upwardly with respect to the ground, and a cross-sectional area of the light splitting member may increase from an upper end to a lower end of the light splitting member.

According to the exemplary embodiment, a part of the laser light incident from the upper portion of the housing may be reflected from the upper surface and be incident to the profile measuring member, another part of the laser light incident from the upper portion of the housing may be refracted on the upper surface and be incident on the lower surface, and the laser light incident on the lower surface may be incident to the power measuring member.

According to the exemplary embodiment, a part of the laser light incident to the power measuring member may be reflected and incident to the light splitting member, and the laser light incident to the light splitting member may be refracted.

According to the exemplary embodiment, the profile measuring member may further include an optical filter for filtering a specific wavelength of the laser light.

Still another exemplary embodiment of the present invention provides a substrate treating apparatus for treating a mask including a plurality of cells, the substrate treating apparatus including: a housing having a treatment space; a support unit is configured to support and rotate a mask in the treatment space; a liquid supply unit is configured to supply a liquid to the mask supported by the support unit; a laser unit including a laser irradiation unit which irradiates laser light to the mask supported by the support unit; a home port providing a standby position in which the laser unit waits; and a moving unit for moving the laser unit between a process position at which the laser light is irradiated to the mask and the standby position, in which the home port detects a characteristic of the laser light from the laser light irradiated by the laser unit.

According to the exemplary embodiment, the home port may include: a housing having an inner space; a profile measuring member installed in the housing and measuring a focal distribution among characteristics of the laser light; a power measuring member installed in the housing and measuring power among the characteristics of the laser light; and a light splitting member for splitting the laser light incident from an upper portion of the housing to the profile measuring member and the power measuring member.

According to the exemplary embodiment, the profile measuring member may be installed on a side wall of the housing, the power measuring member may be installed on a bottom wall of the housing, and the light splitting member may be disposed in the inner space of the housing.

According to the exemplary embodiment, the upper surface of the light splitting member may be formed to be inclined upwardly at a first angle with respect to the ground, and the lower surface of the light splitting member may be formed to be inclined upwardly at a second angle with respect to the ground, the second angle may be greater than the first angle, and a surface of the light splitting member facing the power measuring member may be anti-reflectively coated.

According to the exemplary embodiment, the substrate treating apparatus may further include a lifting member installed at a lower end of the home port to move the housing, in which the profile measuring member may further include an optical filter for filtering a specific wavelength of the laser light.

According to the exemplary embodiment of the present invention, it is possible to perform precise etching on a substrate.

Further, according to the exemplary embodiment of the present invention, it is possible to detect a characteristic of light in the home port.

Further, according to the exemplary embodiment of the present invention, it is possible to detect a profile of light and power of light from irradiated light in the home port.

Further, according to the exemplary embodiment of the present invention, it is possible to accurately measure characteristics of light.

Further, according to the exemplary embodiment of the present invention, it is possible to minimize measurement interference of a light profile due to refracted or scattered light.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a diagram illustrating a normal distribution with respect to a critical dimension of a monitoring pattern and a critical dimension of an anchor pattern.

FIG. 2 is a top plan view schematically illustrating a substrate treating apparatus according to an exemplary embodiment of the present invention.

FIG. 3 is a diagram schematically illustrating a substrate treated in a liquid treating chamber of FIG. 2 viewed from the top.

FIG. 4 is a diagram schematically illustrating an exemplary embodiment of the liquid treating chamber of FIG. 2.

FIG. 5 is a diagram of the liquid treating chamber of FIG. 4 viewed from the top.

FIG. 6 is a diagram schematically illustrating an irradiating module of FIG. 4 viewed from the front.

FIG. 7 is a diagram schematically illustrating the irradiating module of FIG. 6 viewed from the top.

FIG. 8 is a diagram schematically illustrating an exemplary embodiment of a detecting unit of FIG. 4.

FIG. 9 is a diagram schematically illustrating a light splitting member of FIG. 8 viewed from the front.

FIG. 10 is a view schematically illustrating a state in which a part of the light incident on an upper portion of a housing of FIG. 8 is incident to a profile measuring member.

FIG. 11 is a diagram schematically illustrating a state in which another part of the light incident on the upper portion of the housing of FIG. 10 is incident to a power measuring member.

FIG. 12 is a diagram schematically illustrating a state in which a part of the light incident to the power measuring member of FIG. 11 is incident to the light splitting member.

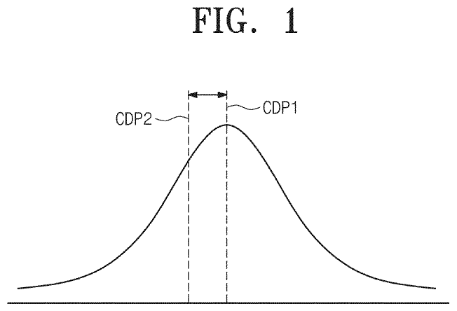

### DETAILED DESCRIPTION

Hereinafter, an exemplary embodiment of the present invention will be described in more detail with reference to the accompanying drawings. An exemplary embodiment of the present invention may be modified in various forms, and the scope of the present invention should not be construed as being limited by the exemplary embodiment described below. The present exemplary embodiment is provided to more completely explain the present invention to those skilled in the art. Therefore, the shapes of components in the drawings are exaggerated to emphasize a clearer description.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

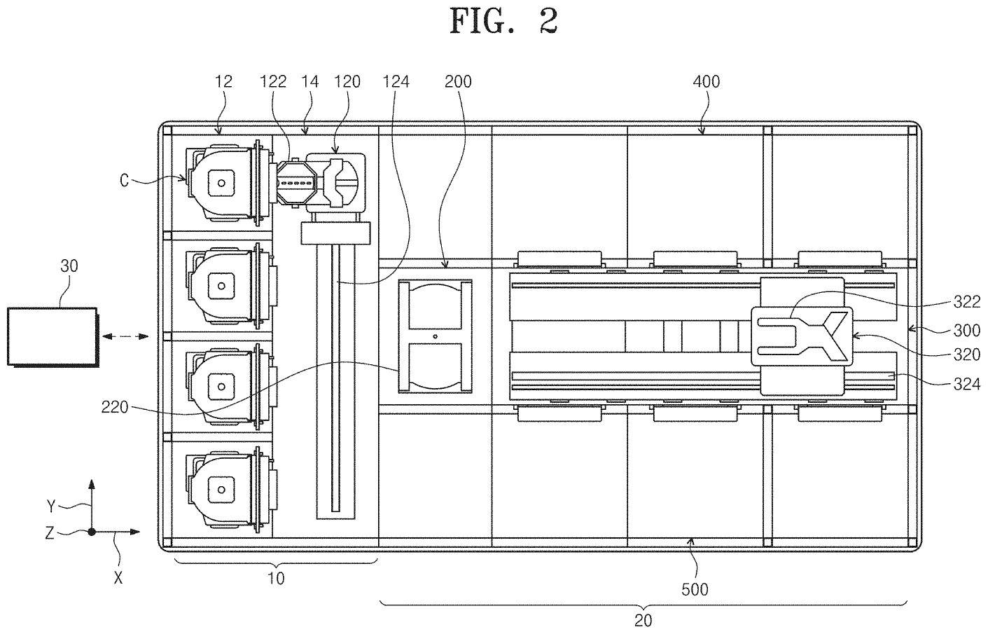

Hereinafter, an exemplary embodiment of the present invention will be described in detail with reference to FIGS. 2 to 12. FIG. 2 is a top plan view schematically illustrating a substrate treating apparatus according to an exemplary embodiment of the present invention.

Referring to FIG. 2, a substrate treating apparatus 1 includes an index module 10, a treating module 20, and a controller 30. According to the exemplary embodiment, the index module 10 and the treating module 20 may be disposed along one direction when viewed from the top.

Hereinafter, the direction in which the index module 10 and the treating module 20 are arranged is defined as a first direction X, when viewed from the front, a direction perpendicular to the first direction X is defined to as a second direction Y, and a direction perpendicular to a plane including both the first direction X and the second direction Y is defined as a third direction Z.

The index module 10 transfers a substrate M from a container C in which the substrate M is accommodated to the treating module 20 that treats the substrate M. In addition, the index module 10 accommodates the substrate M on which a predetermined treatment has been completed in the treating module 20 in the container C. A longitudinal direction of the index module 10 may be formed in the second direction Y. The index module 10 may have a load port 12 and an index frame 14.

The container C in which the substrate M is accommodated is seated on the load port 12. The load port 12 may be located on the opposite side of the treating module 20 with respect to the index frame 14. A plurality of load ports 12 may be provided. The plurality of load ports 12 may be arranged in a line along the second direction Y. The number of load ports 120 may be increased or decreased according to process efficiency of the treating module 20 and a condition of foot print, and the like.

As the container C, an airtight container, such as a Front Opening Unfed Pod (FOUP) may be used. The container C may be placed on the load port 12 by a transfer means (not illustrated), such as an overhead transfer, an overhead conveyor, or an automatic guided vehicle, or an operator.

The index frame 14 provides a transport space for transporting the substrate M. The index frame 14 is provided with an index robot 120 and an index rail 124. The index robot 120 transfers the substrate M. The index robot 120 may transfer the substrate M between the index module 10 and a buffer unit 200 to be described later. The index robot 120 includes an index hand 122. The substrate M may be placed on the index hand 122. The index hand 122 may be provided to be movable forward and backward, rotatable about the third direction Z, and movable in the third direction Z. A plurality of hands 122 may be provided. The plurality of index hands 122 may be provided to be spaced apart from each other in the vertical direction. The plurality of index hands 122 may move forward and backward independently of each other.

The index rail 124 is provided within the index frame 14. A longitudinal direction of the index rail 124 is provided along the second direction Y. The index robot 120 is placed on the index rail 124, and the index robot 120 may be provided to be movable in a straight line on the index rail 124.

The controller 30 may control the substrate treating apparatus 1. The controller 30 may control components provided to the substrate treating apparatus 1. The controller 30 may include a process controller formed of a microprocessor (computer) that executes the control of the substrate treating apparatus, a user interface formed of a keyboard in which an operator performs a command input operation or the like in order to manage the substrate treating apparatus, a display for visualizing and displaying an operation situation of the substrate treating apparatus, and the like, and a storage unit storing a control program for executing the process executed in the substrate treating apparatus under the control of the process controller or a program, that is, a treatment recipe, for executing the process in each component according to various data and treatment conditions. Further, the user interface and the storage unit may be connected to the process controller. The treatment recipe may be stored in a storage medium in the storage unit, and the storage medium may be a hard disk, and may also be a portable disk, such as a CD-ROM or a DVD, or a semiconductor memory, such as a flash memory.

The treating module 20 may include a buffer unit 200, a transfer frame 300, and a liquid treating chamber 400. The buffer unit 200 provides a space in which the substrate M loaded to the treating module 20 and the substrate M unloaded from the treating module 20 temporarily stay. The transfer frame 300 provides a space for transferring the substrate M between the buffer unit 200, the liquid treating chamber 400, and a drying chamber 500. The liquid treating chamber 400 performs a liquid treatment process of liquid-treating the substrate M by supplying a liquid onto the substrate M. The drying chamber 500 performs a drying process of drying the substrate M for which the liquid treatment has been completed.

The buffer unit 200 may be disposed between the index frame 14 and the transfer frame 300. The buffer unit 200 may be located at one end of the transfer frame 300. A slot 220 in which the substrate M is placed is provided inside the buffer unit 200. A plurality of slots (not illustrated) may be provided. The plurality of slots (not illustrated) may be spaced apart from each other in the third direction Z.

A front face and a rear face of the buffer unit 200 are opened. The front face is a surface facing the index module 10, and the rear face is a surface facing the transfer frame 300. The index robot 120 may approach the buffer unit 200 through the front face, and a transfer robot 320 to be described later may approach the buffer unit 200 through the rear face.

A longitudinal direction of the transfer chamber 300 may be provided in the first direction X. The liquid treating chamber 400 and the drying chamber 500 may be disposed on both sides of the transfer frame 300. The liquid treating chamber 400 and the drying chamber 500 may be disposed on the side of the transfer frame 300. The transfer frame 300 and the liquid treating chamber 400 may be disposed in the second direction Y. The transfer frame 300 and the drying chamber 500 may be disposed in the second direction Y.

According to the exemplary embodiment, the liquid treating chambers 400 may be disposed on both sides of the transfer frame 300. On one side of the transfer frame 300, the liquid treating chambers 400 may be provided in an arrangement of A×B (A and B are each 1 or a natural number greater than 1) in each of the first direction X and the third direction Z.

The transfer frame 300 includes the transfer robot 320 and a transfer rail 324. The transfer robot 320 transfers the substrate M. The transfer robot 320 transfers the substrate M between the buffer unit 200, the liquid treating chamber 400, and the drying chamber 500. The transfer robot 320 includes a transfer hand 322 on which the substrate M is placed. The substrate M may be placed on the transfer hand 322. The transfer hand 322 may be provided to be movable forward and backward, rotatable about the third direction Z, and movable along the third direction Z. A plurality of hands 322 are provided while being vertically spaced apart from each other, and the hands 322 may move forward and backward independently of each other.

The transfer rail 324 may be provided inside the transfer frame 300 along the longitudinal direction of the transfer frame 300. For example, the longitudinal direction of the transfer rail 324 may be provided in the first direction X. The transfer robot 320 may be placed on the transfer rail 324, and the transfer robot 320 may be provided to be movable on the transfer rail 324.

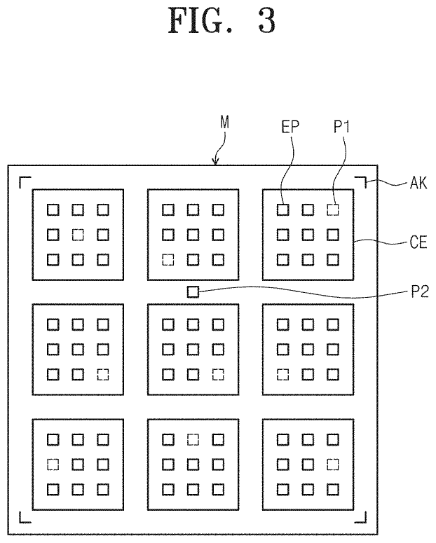

FIG. 3 is a diagram schematically illustrating a substrate treated in a liquid treating chamber of FIG. 2 viewed from the top. Hereinafter, the substrate M treated in the liquid treating chamber 400 according to the exemplary embodiment of the present invention will be described in detail with reference to FIG. 3.

Referring to FIG. 3, an object to be treated in the liquid treating chamber 400 may be a substrate of any one of a wafer, a glass, and a photomask. For example, the substrate M treated in the liquid treating chamber 400 according to the exemplary embodiment of the present invention may be a photo mask that is a ‘frame’ used in the exposure process. The substrate M may have a quadrangular shape. The substrate M may be a photomask that is a ‘frame’ used in the exposure process. At least one reference mark AK may be marked on the substrate M. For example, a plurality of reference marks AK may be formed in each edge region of the substrate M. The reference mark AK may be a mark used for aligning the substrate M called an align key. In addition, the reference mark AK may be a mark used to derive position information of the substrate M. For example, a photographing unit 4550 to be described later may acquire an image by photographing the reference mark AK, and transmit the acquired image to the controller 30. The controller 30 may analyze the image including the reference mark AK to detect the exact position of the substrate M. Also, the reference mark AK may be used to determine the position of the substrate M when the substrate M is transferred.

A cell CE may be formed on the substrate M. At least one cell CE may be formed. For example, the plurality of cells CE may be formed. The plurality of patterns may be formed in each of the plurality of cells CE. The patterns formed in each cell CE may be defined as one pattern group. The patterns formed in each cell CE may include an exposure pattern EP and a first pattern P1.

The exposure pattern EP may be used to form an actual pattern on the substrate M. The first pattern P1 may be a pattern representative of the exposure patterns EP formed in one cell CE. Further, when the cell CE is provided in plurality, the first pattern P1 may be provided in plurality. For example, each of the plurality of cells CE may be provided with the first pattern P1. However, the present invention is not limited thereto, and a plurality of first patterns P1 may be formed in one cell CE. The first pattern P1 may have a shape in which portions of the respective exposure patterns EP are combined. The first pattern P1 may be referred to as a monitoring pattern. An average value of the critical dimensions of the plurality of first patterns P1 may be referred to as a Critical Dimension Monitoring Macro (CDMM).

When an operator inspects the first pattern P1 formed in any one cell CE through a Scanning Electron Microscope (SEM), whether the shape of the exposure patterns EP formed in any one cell CE is satisfactory may be estimated. Accordingly, the first pattern P1 may function as a pattern for inspection. Unlike the above-described example, the first pattern P1 may be any one of the exposure patterns EP participating in the actual exposure process. Optionally, the first pattern P1 may be a pattern for inspection and an exposure pattern participating in the actual exposure at the same time.

The second pattern P2 may be a pattern representative of the exposure patterns EP formed on the entire substrate M. For example, the second pattern P2 may have a shape in which portions of the respective first patterns P1 are combined.

When the operator inspects the second pattern P2 through the SEM, whether the shape of the exposure patterns EP formed on one substrate M is satisfactory may be estimated. Accordingly, the second pattern P2 may function as a pattern for inspection. The second pattern P2 may be a pattern for inspection that does not participate in the actual exposure process. The second pattern P2 may be a pattern for setting process conditions of an exposure apparatus. The second pattern P2 may be referred to as an anchor pattern.

Hereinafter, the liquid treating chamber 400 according to the exemplary embodiment of the present invention will be described in detail. In addition, hereinafter, the present invention will be described based on an example in which the treatment performed in the liquid treating chamber 400 is a Fine Critical Dimension Correction (FCC) in the process of manufacturing the mask for the exposure process.

The substrate M loaded into and treated in the liquid treating chamber 400 may be the substrate M on which a pre-treatment has been performed. Critical dimensions of the first pattern P1 and the second pattern P2 of the substrate M loaded into the liquid treating chamber 400 may be different from each other. According to the exemplary embodiment, the critical dimension of the first pattern P1 may be relatively larger than the critical dimension of the second pattern P2. For example, the critical dimension of the first pattern P1 may have a first width (for example, 69 nm), and the critical dimension of the second pattern P2 may have a second width (for example, 68.5 nm).

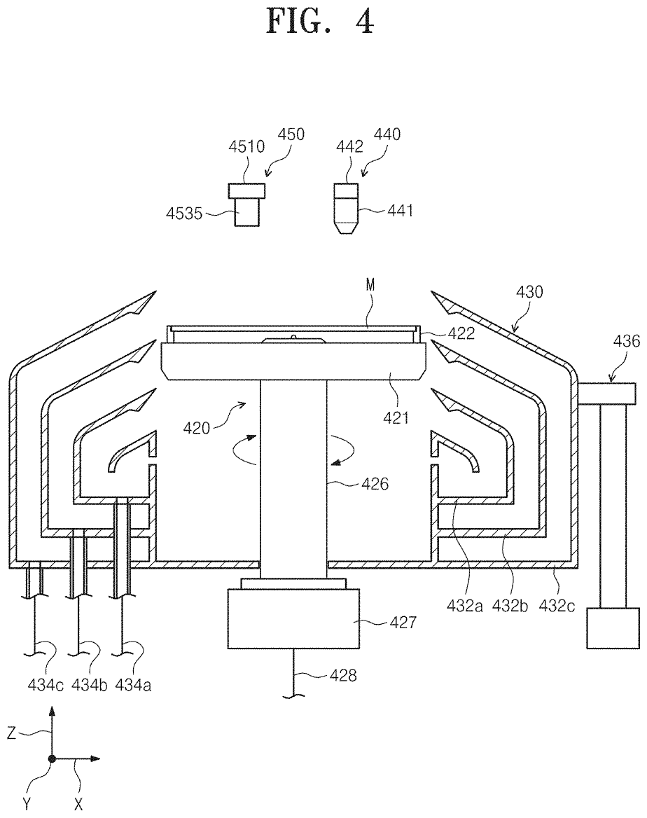

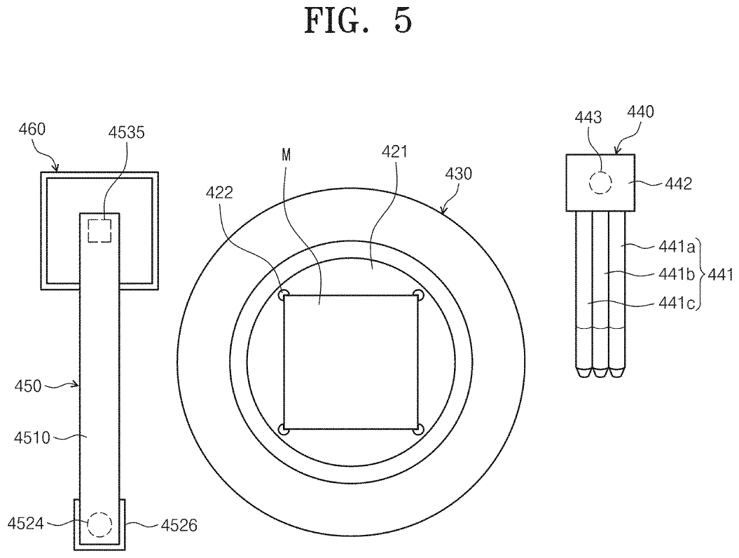

FIG. 4 is a diagram schematically illustrating an exemplary embodiment of the liquid treating chamber of FIG. 2. FIG. 5 is a diagram of the liquid treating chamber of FIG. 4 viewed from the top. Referring to FIGS. 4 and 5, the liquid treating chamber 400 may include a housing 410, a support unit 420, a treating container 430, a liquid supply unit 440, an irradiating module 450, and a home port 460.

The housing 410 has a space therein. The support unit 420, the treating container 430, the liquid supply unit 440, the irradiating module 450, and the home port 460, and a lifting member 470 may be provided in the inner space of the housing 410. The housing 410 may be provided with an entrance (not illustrated) through which the substrate M may be loaded in and out. An inner wall surface of the housing 410 may be coated with a material having high corrosion resistance to chemicals supplied by the liquid supply unit 440.

An exhaust hole (not illustrated) may be formed in a bottom surface of the housing 410. The exhaust hole (not illustrated) may be connected to an exhaust member, such as a pump, capable of exhausting the inner space of the housing 410. Fume and the like that may be generated in the inner space of the housing 410 may be exhausted to the outside of the housing 410 through the exhaust hole (not illustrated).

The support unit 420 supports the substrate M. The support unit 420 may support the substrate M in the treatment space provided by the treating container 430 to be described later. The support unit 420 rotates the substrate M. The support unit 420 may include a body 421, a support pin 422, a support shaft 426, and a driving member 427.

The body 421 may be provided in a plate shape. The body 421 may have a plate shape having a predetermined thickness. When viewed from the top, the body 421 may have an upper surface provided in a generally circular shape. The upper surface of the body 421 may have a relatively larger area than the substrate M. The support pin 422 may be installed in the body 421.

The support pins 422 support the substrate M. The support pin 422 may have a generally circular shape when viewed from the top. When viewed from the top, the support pin 422 may have a shape in which a portion corresponding to the corner region of the substrate M is recessed downward. The support pin 422 may have a first surface and a second surface. For example, the first surface may support the lower portion of the edge region of the substrate M. The second surface may face the side of the edge region of the substrate M. Accordingly, when the substrate M is rotated, the movement of the substrate M in the lateral direction may be restricted by the second surface.

At least one support pin 422 is provided. For example, a plurality of support pins 422 may be provided. The support pins 422 may be provided in a number corresponding to the number of edge regions of the substrate M having a quadrangular shape. The support pin 422 may support the substrate M so that the lower surface of the substrate M and the upper surface of the body 421 are spaced apart from each other.

The support shaft 426 is coupled to the body 421. The support shaft 426 is located below the body 421. The support shaft 426 may be a hollow shaft. A fluid supply line 428 may be formed inside the hollow shaft. The fluid supply line 428 may supply a treatment fluid and/or treatment gas to a lower portion of the substrate M. For example, the treatment fluid may include a chemical or rinse solution. The chemical may be a liquid having acid or basic properties. The rinse solution may be pure water. For example, the treatment gas may be inert gas. The treatment gas may dry the lower portion of the substrate M. However, unlike the above-described example, the fluid supply line 428 may not be provided inside the support shaft 426.

The support shaft 426 may be rotated by the driving member 427. The driving member 427 may be a hollow motor. When the driving member 427 rotates the support shaft 426, the body 421 coupled to the support shaft 426 may rotate. The substrate M may be rotated with the rotation of the body 421 through the support pin 422.

The treating container 430 has a treatment space. The treating container 430 has a treatment space in which the substrate M is treated. According to the example, the treating container 430 may have a treatment space with an open top. The treating container 430 may have a cylindrical shape with an open top. The substrate M may be subjected to liquid treatment and heat treatment in the treatment space. The treating container 430 may prevent the treatment liquid supplied to the substrate M from scattering to the housing 410, the liquid supply unit 440, and the irradiating module 450.

The treating container 430 may have a plurality of recovery containers 432a, 432b, and 432c. Each of the recovery containers 432a, 432b, and 432c may separate and recover different liquids among the liquids used for treating the substrate M. Each of the recovery containers 432a, 432b, and 432c may have a recovery space for recovering a liquid used for treating the substrate M. Each of the recovery containers 432a, 432b, and 432c may be provided in an annular ring shape surrounding the support unit 420 when viewed from the top. When the liquid treatment process is performed, the liquid scattered by the rotation of the substrate M is introduced into the recovery space through the inlet, which is an interspace formed between the respective recovery containers 432a, 432b, and 432c. Different types of treatment liquids may be introduced into the recovery containers 432a, 432b, and 432c, respectively.

According to an example, the treating container 430 may include a first recovery container 432a, a second recovery container 432b, and a third recovery container 432c. The first recovery container 432a may be provided in an annular ring shape surrounding the support unit 420. The second recovery container 432b may be provided in an annular ring shape surrounding the first recovery container 432a. The third recovery container 432c may be provided in an annular ring shape surrounding the second recovery container 432b.

Recovery lines 434a, 434b, and 434c extending vertically downward from the bottoms of the recovery containers 432a, 432b, and 432c may be connected to the recovery containers 432a, 432b, and 432c, respectively. Each of the recovery lines 434a, 434b, and 434c may discharge the treatment liquid introduced through the recovery containers 432a, 432b, and 432c, respectively. The discharged treatment liquid may be reused through an external treatment liquid regeneration system (not illustrated).

The treating container 430 is coupled to the lifting member 436. The lifting member 436 may move the treating container 430. For example, the lifting member 436 may change the position of the treating container 430 in the third direction Z. The lifting member 436 may be a driving device that moves the treating container 430 in the vertical direction. The lifting member 436 may move the treating container 430 in the upper direction while the liquid treatment and/or heating treatment is performed on the substrate M. The lifting member 436 may move the treatment container 430 in the down direction when the substrate M is loaded into the inner space or when the substrate M is unloaded from the inner space.

The liquid supply unit 440 may supply a liquid onto the substrate M. The liquid supply unit 440 may supply a treatment liquid for liquid-treating the substrate M. The liquid supply unit 440 may supply the treatment liquid to the substrate M supported by the support unit 420. For example, the liquid supply unit 440 may supply the treatment liquid to the substrate M on which the first pattern P1 formed in the plurality of cells CE and the second pattern P2 formed outside the region where the cells CE are formed.

The treatment liquid may be provided as an etching solution or a rinse solution. The etching solution may be a chemical. The etching solution may etch the pattern formed on the substrate M. The etching solution may be referred to as an etchant. The etchant may be a liquid containing hydrogen peroxide and a mixture in which ammonia, water, and an additive are mixed. The rinse solution may clean the substrate M. The rinse solution may be provided as a known chemical liquid.

Referring to FIG. 5, the liquid supply unit 440 may include a nozzle 441, a fixed body 442, a rotation shaft 443, and a rotation member 444. The nozzle 441 may supply the treatment liquid to the substrate M supported by the support unit 420. One end of the nozzle 441 may be connected to the fixed body 442, and the other end of the nozzle 441 may extend from the fixed body 442 toward the substrate M. The nozzle 441 may extend from the fixed body 442 in the first direction X. The other end of the nozzle 441 may be bent and extended at a predetermined angle in a direction toward the substrate M supported by the support unit 420.

The nozzle 441 may include a first nozzle 441a, a second nozzle 441b, and a third nozzle 441c. Any one of the first nozzle 441a, the second nozzle 441b, and the third nozzle 441c may supply a chemical among the above-described treatment liquids. Further, another one of the first nozzle 441a, the second nozzle 441b, and the third nozzle 441c may supply a rinse solution among the above-described treatment liquids. Another one of the first nozzle 441a, the second nozzle 441b, and the third nozzle 441c may supply different types of chemicals from those supplied by any one of the first nozzle 441a, the second nozzle 441b, and the third nozzle 441c.

The fixed body 442 may fix and support the nozzle 441. The fixed body 442 may be connected to the rotation shaft 443 rotated based on the third direction Z by the rotation member 444. When the rotation member 444 rotates the rotation shaft 443, the fixed body 442 may be rotated about the third direction Z. Accordingly, a discharge port of the nozzle 441 may be moved between a liquid supply position, which is a position where the treatment liquid is supplied to the substrate M, and a standby position, which is a position where the treatment liquid is not supplied to the substrate M.

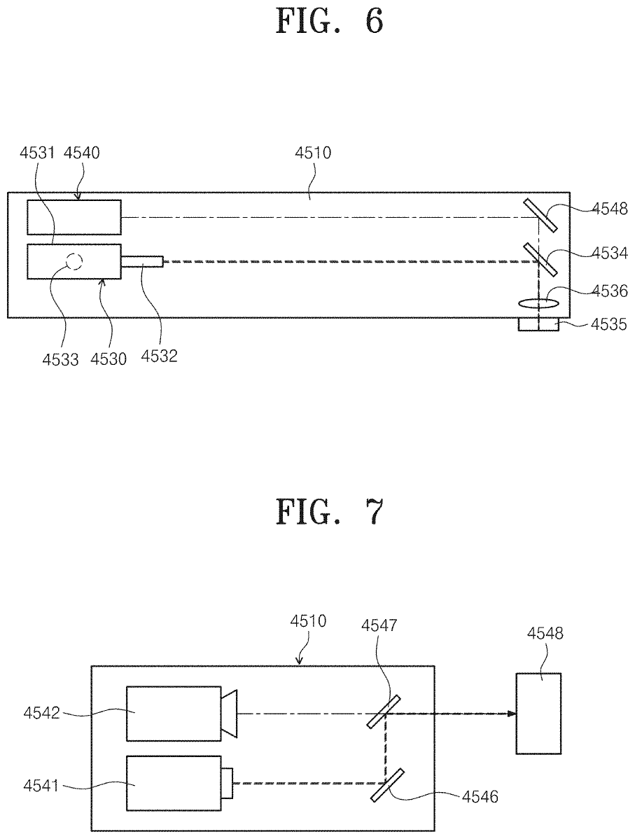

FIG. 6 is a diagram schematically illustrating the irradiating module of FIG. 4 viewed from the front. FIG. 7 is a diagram schematically illustrating the irradiating module of FIG. 6 viewed from the top.

Referring to FIGS. 6 and 7, the irradiating module 450 may emit light to the substrate M. For example, the irradiating module 450 may perform a heat treatment on the substrate M. In addition, the irradiating module 450 may photograph an image and/or an image in which the substrate M is heat-treated. The irradiating module 450 may include a housing 4510, a moving unit 4520, a laser unit 4540, and a photographing unit 4550.

The housing 4510 has an installation space therein. The laser unit 4530 and the photographing unit 4540 may be located in the installation space of the housing 4510. For example, the laser unit 4530, a camera unit 4542, and the lighting unit 4544 may be located in the installation space of the housing 4510. The housing 4510 protects the laser unit 4530 and the photographing unit 4540 from particles, fumes, or scattered droplets generated during the process.

An opening may be formed in a lower portion of the housing 4510. An irradiation end 4535 to be described later may be inserted into the opening of the housing 4510. When the irradiation end 4535 is inserted into the opening of the housing 4510, one end of the irradiation end 4535 may protrude from the lower end of the housing 4510. For example, a portion of a barrel 4537 to be described later may protrude from the lower end of the housing 4510.

The moving unit 4520 moves the housing 4510. The moving unit 4520 may move the irradiation end 4535 to be described later by moving the housing 4510. The moving unit 4520 may include a driver 4522, a shaft 4524, and a moving member 4526.

The driver 4522 may be a motor. The driver 4522 may be connected to the shaft 4524. The actuator 4522 may move the shaft 4524 in the vertical direction. The driver 4522 may rotate the shaft 4524. For example, a plurality of drivers 4522 may be provided. Any one of the plurality of drivers 4522 may be provided as a rotary motor for rotating the shaft 4524, and the other of the plurality of drivers 4522 may be provided as a linear motor for moving the shaft 4524 in the vertical direction.

The shaft 4524 may be connected to the housing 4510. The shaft 4524 may be connected to the housing 4510 via the moving member 4526. As the shaft 4524 rotates, the housing 4510 may also rotate. Accordingly, the position of the irradiation end 4535 to be described later may also be changed. For example, the position of the irradiation end 4535 may be changed in the third direction Z. In addition, the position of the irradiation end 4535 may be changed in the third direction Z as a rotation axis.

When viewed from the top, the center of the irradiation end 4535 may move in an arc toward the center of the shaft 4524. When viewed from the top, the center of the irradiation end 4535 may be moved to pass through the center of the substrate M supported by the support unit 420. The irradiation end 4535 may be moved between a process position where the laser light L is irradiated to the substrate M and a standby position where the substrate waits without performing the heat treatment on the substrate M by the moving unit 4520. The home port 460 to be described later is located in the standby position.

The moving member 4526 may be provided between the housing 4510 and the shaft 4524. The moving member 4526 may be an LM guide. The moving member 4526 may move the housing 4510 laterally. The moving member 4526 may move the housing 4510 in the first direction X and/or the second direction Y. The position of the irradiation end 4535 may be variously changed by the driver 4522 and the moving member 4526.

The laser unit 4530 may heat the substrate M. The laser unit 4530 may heat the substrate M supported by the support unit. The laser unit 4530 may heat a partial region of the substrate M. The laser unit 4530 may heat a specific region of the substrate M. The laser unit 4530 may be supplied with a chemical to heat the substrate M on which the liquid film is formed. The laser unit 4530 may heat the pattern formed on the substrate M. The laser unit 4530 may heat any one of the first pattern P1 and the second pattern P2. The laser unit 4530 may heat the second pattern P2 between the first pattern P1 and the second pattern P2. According to the exemplary embodiment, the laser unit 4530 may heat the second pattern P2 by irradiating the laser light L.

The laser unit 4530 may include a laser irradiation unit 453, a beam expander 4532, a tilting member 4533, a lower reflective member 4534, and a lens member 4535. The laser irradiation unit 4531 irradiates the laser light L. The laser irradiation unit 4531 may irradiate the laser light L having straightness. The laser light L irradiated from the laser irradiation unit 4531 may be irradiated to the substrate M through the lower reflective member 4534 and the lens member 4535, which will be described later, in turn. For example, the laser light L irradiated from the laser irradiation unit 4531 may be irradiated to the second pattern P2 formed on the substrate M through the lower reflective member 4534 and the lens member 4535 in turn.

The beam expander 4532 may control the characteristics of the laser light L irradiated from the laser irradiation unit 4531. The beam expander 4532 may adjust the shape of the laser light L irradiated from the laser irradiation unit 4531. In addition, the beam expander 4532 may adjust the profile of the laser light L irradiated from the laser irradiation unit 4531. For example, the diameter of the laser light L irradiated from the laser irradiation unit 4531 may be changed in the beam expander 4532. The diameter of the laser light L irradiated by the laser irradiation unit 4531 may be expanded or reduced in the beam expander 4532.

The tilting member 4533 may tilt the irradiation direction of the laser light L irradiated by the laser irradiation unit 4531. The tilting member 4533 may rotate the laser irradiation unit 4531 about one axis. The tilting member 4533 may tilt the irradiation direction of the laser light L irradiated from the laser irradiation unit 4531 by rotating the laser irradiation unit 4531. The tilting member 4533 may include a motor.

The lower reflective member 4534 may change the irradiation direction of the laser light L irradiated from the laser irradiation unit 4531. For example, the lower reflective member 4534 may change the irradiation direction of the laser light L irradiated in the horizontal direction to the vertical downward direction. For example, the lower reflective member 4534 may change the irradiation direction of the laser light L to a direction toward the irradiation end 4535, which will be described later. The laser light L refracted by the lower reflective member 4534 may be transmitted to the substrate M that is a to-be-treated object or a detecting unit 4640 provided inside the home port 460 to be described later through the lens member 4535 to be described later.

When viewed from the top, the lower reflective member 4534 may be positioned to overlap an upper reflective member 4548 to be described later. The lower reflective member 4534 may be disposed below the upper reflective member 4548. The lower reflective member 4534 may be tilted at the same angle as the upper reflective member 4548.

The lens member 4535 may include a lens 4536 and a barrel 4537. For example, the lens 4536 may be an objective lens. The barrel 4537 may be installed at the lower end of the lens. he barrel 4537 may have a generally cylindrical shape. The barrel 4537 may be inserted into an opening formed at the lower end of the housing 4510. One end of the barrel 4537 may be positioned to protrude from the lower end of the housing 4510.

The lens member 4535 may function as the irradiation end 4535 through which the laser light L is irradiated to the substrate M. The laser light L irradiated by the laser unit 4530 may be irradiated to the substrate M through the irradiation end 4535. The image photographing of the camera unit 4542 may be provided through the irradiation end 4535. The light irradiated by the lighting module 4544 may be provided through the irradiation end 4535.

The photographing unit 4540 may photograph the laser light L irradiated from the laser unit 4530. The photographing unit 4540 may acquire an image, such as an image and/or a photo, of a region to which the laser light L is irradiated from the laser module 4330. The photographing unit 4540 may monitor the laser light L irradiated from the laser irradiation unit 4531. The photographing unit 4540 may acquire an image and/or a video of the laser light L irradiated from the laser irradiation unit 4531.

The photographing unit 4540 may monitor information of the laser light L. For example, the photographing unit 4540 may monitor diameter information of the laser light L. Also, the photographing unit 4540 may monitor center information of the laser light L. Also, the photographing unit 4540 may monitor profile information of the laser light L. The photographing unit 4540 may include the camera unit 4542, the lighting unit 4544, and the upper reflective member 4548.

The camera unit 4542 acquires an image of the laser light L irradiated from the laser irradiation unit 4531. For example, the camera unit 4542 may acquire an image including a point to which the laser light L irradiated from the laser irradiation unit 4531 is irradiated. Also, the camera unit 4542 acquires an image of the substrate M supported by the support unit 420.

The camera unit 4542 may be a camera. A photographing direction in which the camera unit 4542 acquires an image may face the upper reflective member 4548, which will be described later. The camera unit 4542 may transmit the acquired image to the controller 30.

The lighting unit 4544 may provide light so that the camera unit 4542 is capable of acquiring an image. The lighting unit 4544 may include a lighting member 4545, a first reflection plate 4546, and a second reflective plate 4547. The lighting member 4545 irradiates light. The lighting member 4545 provides light. Light provided by the lighting member 4545 may be sequentially reflected along the first reflective plate 4546 and the second reflective plate 4547. The light provided by the lighting member 4545 may be reflected from the second reflective plate 4547 and may be irradiated in a direction toward the upper reflective member 4548 to be described later.

The upper reflective member 4548 may change the photographing direction of the camera unit 4542. For example, the upper reflective member 4548 may change the photographing direction of the camera unit 4542, which is the horizontal direction, to the vertical downward direction. For example, the upper reflective member 4548 may change the photographing direction of the camera unit 4542 to face the irradiation end 4535. The upper reflective member 4548 may change the irradiation direction of light from the lighting member 4545 sequentially passing and transmitted through the first reflective plate 4546 and the second reflective plate 4547 from the horizontal direction to the vertical downward direction. For example, the upper reflective member 4548 may change the irradiation direction of the light of the lighting unit 4544 toward the irradiation end 4535.

The upper reflective member 4548 and the lower reflective member 4534 may be positioned to overlap each other when viewed from above. The upper reflective member 4548 may be disposed above the lower reflective member 4534. The upper reflective member 4548 and the lower reflective member 4534 may be tilted at the same angle. The upper reflective member 4548 and the lower reflective member 4534 may be provided so that the irradiation direction of the laser light L irradiated by the laser irradiation unit 4531, the photographing direction in which the camera unit 4542 acquires the image, and the irradiation direction of the light provided by the illumination unit 4544 are coaxial when viewed from the above.

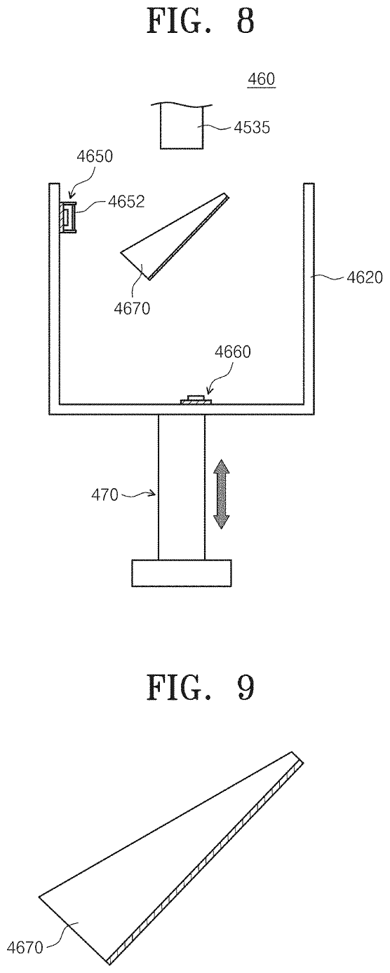

FIG. 8 is a diagram schematically illustrating an exemplary embodiment of the detecting unit of FIG. 4. FIG. 9 is a diagram schematically illustrating a light splitting member of FIG. 8 viewed from the front. Hereinafter, the home port and the detecting unit according to the exemplary embodiment of the present invention will be described in detail with reference to FIGS. 8 and 9.

Referring to FIG. 8, the home port 460 is located in the inner space of the housing 410. The home port 460 may be installed in a region below the irradiation end 4535 when the irradiation end 4535 is in the standby position by the moving unit 4520. That is, the home port 460 provides the standby position where the laser unit 4530 waits. The home port 460 may include the housing 4620 and the detecting unit 4640.

The housing 4620 has an installation space therein. A profile measuring member 4650 to be described later may be installed on a side surface of the housing 4620. A power measuring member 4660 to be described later may be installed on the bottom of the housing 4620. A light splitting member 4670 to be described later may be installed in the inner installation space of the housing 4620. An upper portion of the housing 4620 may be opened. When the irradiation end 4535 is in the standby position, the irradiation end 4535 may be located above the housing 4620.

Unlike the foregoing, the upper portion of the housing 4620 is not opened, and an opening may be formed in the upper portion of the housing 4620. When the irradiation end 4535 is in the standby position, the opening formed in the upper portion of the housing 4620 may be formed in a region corresponding to the center of the irradiation end 4535.

The detecting unit 4640 is located in the installation space inside the housing 4620. The detecting unit 4640 detects a characteristic of the laser light L from the laser light L irradiated by the laser unit 4530. The detecting unit 4640 may include the profile measuring member 4650, the power measuring member 4660, and the light splitting member 4670.

The profile measuring member 4650 is installed in the installation space inside the housing 4620. For example, the profile measuring member 4650 may be installed on one sidewall of the housing 4620. The profile measuring member 4650 measures the focal distribution of the laser light L among the characteristics of the laser light L irradiated from the laser unit 4530. For example, the profile measuring member 4650 may measure the focal distribution of the laser light L irradiated from the laser unit 4530 from first light L1 split by the light splitting member 4670 to be described later.

The focal distribution may refer to a light profile. Data for the distribution area of the laser light L included in the laser light L, the intensity of the laser light L, the uniformity of the laser light L, or the size of the laser light L may be obtained from the focal distribution.

The profile measuring member 4650 may include an attenuation filter 4652. The attenuation filter 4652 may be provided as a filter that allows only a wavelength having a characteristic band included in the first light L1 split by the light splitting member 4670 to be described later to pass. Optionally, the attenuation filter 4652 may also be provided as a filter that reflects only a wavelength having a specific band included in the first light L1 split by the light splitting member 4670. The attenuation filter 4652 may be variously modified and provided as a known optical filter.

The power measuring member 4660 is installed in the installation space inside the housing 4620. For example, the power measuring member 4660 may be installed on the bottom wall of the housing 4620. The power measuring member 4660 measures the power of the laser light L among the characteristics of the laser light L irradiated from the laser unit 4530. For example, the power measuring member 4660 may measure the power of the laser light L irradiated from the laser unit 4530 from second light L2 split by the light splitting member 4670 to be described later.

The light splitting member 4670 is located in the installation space inside the housing 4620. The light splitting member 4670 is positioned in the installation space inside the housing 4620 by a member (not illustrated). For example, the light splitting member 4670 is located in the installation space of the housing 4620, but may be spaced apart from the bottom wall and side walls of the housing 4620.

The light splitting member 4670 has an upper surface and a lower surface. An upper surface of the light splitting member 4670 may be formed at a position overlapping the irradiation end 4535 when viewed from the top. For example, the upper surface of the light splitting member 4670 may be positioned to overlap the center of the irradiation end 4535 when viewed from the top. The upper surface of the light splitting member 4670 is formed to be inclined when viewed from the side. For example, the upper surface of the light splitting member 4670 may be formed to be inclined upwardly at a first angle A1 with respect to the ground when viewed from the side.

The laser light L irradiated from the irradiation end 4535 is split into the first light L1 and the second light L2 on the upper surface of the light splitting member 4670. According to the exemplary embodiment, the first light L1 may be light, which has been irradiated from the irradiation end 4535, reflected from the upper surface of the light splitting member 4670. The second light L2 may be light, which has been irradiated from the irradiation end 4535, refracted on the upper surface of the light splitting member 4670.

The first angle A1 may be formed at an angle at which the first light L1 reflected from the upper surface of the light splitting member 4670 among the laser light L irradiated from the irradiation end 4535 may be incident to the profile measuring member 4650.

A lower surface of the light splitting member 4670 is formed to face the power measuring member 4660. The lower surface of the light splitting member 4670 is provided at a position overlapping the power measuring member 4660 when viewed from above. The lower surface of the light splitting member 4670 is formed to be inclined when viewed from the side. For example, the lower surface of the light splitting member 4670 may be formed to be inclined upwardly at a second angle A2 with respect to the ground when viewed from the side. According to the example, the second angle A2 may be greater than the first angle A1.

The second angle A2 may be formed at an angle at which the second light L2 refracted from the upper surface of the light splitting member 4670 among the laser light L irradiated from the irradiation end 4535 is refracted again on the lower surface of the light splitting member 4670 and is incident to the power measuring member 4660. Accordingly, the light splitting member 4670 may split the laser light L incident from the upper portion of the housing 4620 to the profile measuring member 4650 and the power measuring member 4660.

The lower surface of the light splitting member 4670 may be treated with anti-reflection coating. The laser light L may not be reflected on the lower surface of the light splitting member 4670. For example, the laser light L may be refracted, but not reflected, on the lower surface of the light splitting member 4670.

The lifting member 470 is disposed in the housing 410. The lifting member 470 may be coupled to the home port 460. The lifting member 470 may be installed at the lower end of the housing 4620. The lifting member 470 changes the position of the housing 4620. For example, the lifting member 470 may vertically move the housing 4620. The lifting member 470 may move the housing 4620 to a preset height.

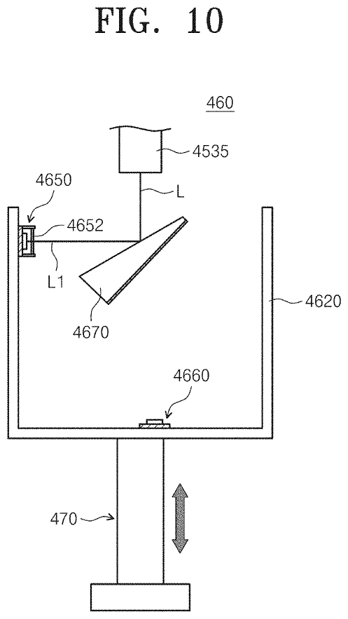

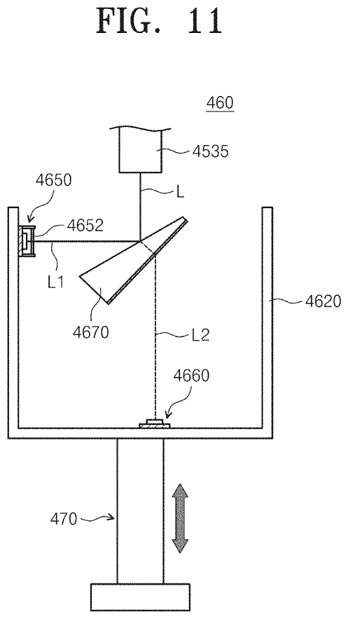

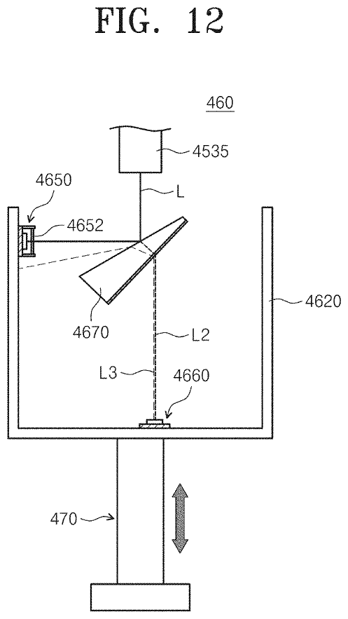

FIG. 10 is a view schematically illustrating a state in which a part of the light incident on the upper portion of the housing of FIG. 8 is incident to the profile measuring member. FIG. 11 is a diagram schematically illustrating a state in which another part of the light incident on the upper portion of the housing of FIG. 10 is incident to the power measuring member. FIG. 12 is a diagram schematically illustrating a state in which a part of the light incident to the power measuring member of FIG. 11 is incident to the light splitting member.

Hereinafter, a mechanism for detecting the characteristics of the laser light L irradiated from the laser unit 4530 according to the exemplary embodiment of the present invention will be described in detail with reference to FIGS. 10 to 12.

Referring to FIG. 10, the irradiation end 4535 of the laser unit 4530 may be located in the standby position. The irradiation end 4535 may be located at the top of the home port 460 that is the standby position. The standby position where the irradiation end 4535 is located may be a position overlapping the light splitting member 4670 when viewed from the top. After the irradiation end 4535 is positioned at the standby position, the laser unit 4530 irradiates the laser light L in a direction toward the light splitting member 4670.

The first light L1, which is a part of the laser light L irradiated toward the light splitting member 4670, is reflected from the upper surface of the light splitting member 4670 and travels toward the profile measuring member 4650. For example, the first light L1, which is a part of the laser light L irradiated toward the light splitting member 4670, is reflected from the upper surface of the light splitting member 4670 inclined at a first inclination D1 and travels toward the profile measuring member 4650.

The first light L1 passes through the attenuation filter 4652 and is incident to the profile measuring member 4650. The focal distribution of the laser light L irradiated by the laser unit 4530 may be measured from the first light L1 incident to the profile measuring member 4650. That is, the profile of the laser light L irradiated by the laser unit 4530 may be measured from the first light L1. For example, the profile measuring member 4650 may obtain data for the distribution area of the laser light L included in the laser light L, the intensity of the laser light L, the uniformity of the laser light L, or the size of the laser light L from the first light L1.

Referring to FIG. 11, the second light L1, which is another part of the laser light L irradiated toward the light splitting member 4670, is refracted from the upper surface of the light splitting member 4670 and is incident on the lower surface of the light splitting member 4670. The second light L2 incident on the lower surface of the light splitting member 4670 is refracted from the lower surface of the light splitting member 4670 inclined at a second inclination D2 and travels toward the power measuring member 4660.

The second light L2 is incident to the power measuring member 4660. The power of the laser light L irradiated by the laser unit 4530 may be measured from the second light L2 incident to the power measuring member 4660. That is, an absolute value of the power of the laser light L irradiated by the laser unit 4530 may be measured by the power measuring member 4660.

Referring to FIG. 12, a part of the second light L2 incident to the power measuring member 4660 may be reflected by the power measuring member 4660. Hereinafter, the light reflected by the power measuring member 4660 in the second light L2 incident to the power measuring member 4660 is defined as noise light L3.

The noise light L3 is reflected by the power measuring member 4660 and travels to the light splitting member 4670. The noise light L3 is incident on the lower surface of the light splitting member 4670. According to the exemplary embodiment of the present invention, since the lower surface of the light splitting member 4670 is coated with a material that does not reflect light, the noise light L3 is prevented from being reflected from the lower surface of the light splitting member 4670 again. Accordingly, the noise light L3 is prevented from re-entering the profile measuring member 4650 through the light splitting member 4670. That is, the light splitting member 4670 according to the exemplary embodiment of the present invention refracts the noise light L3 reflected from the power measuring member 4660 without reflection.

Also, according to the exemplary embodiment of the present invention, the lower surface of the light splitting member 4670 may be formed with the second inclination D2. Accordingly, the noise light L3 incident on the lower surface of the light splitting member 4670 is refracted and incident on the upper surface of the light splitting member 4670.

A position at which the noise light L3 is incident on the upper surface of the light splitting member 4670 is different from a position at which the laser light L irradiated from the irradiation end 4535 is incident on the upper surface of the light splitting member 4670. This is because the lower surface of the light splitting member 4670 according to the exemplary embodiment of the present invention is provided with the second inclination D2 inclined upwardly with respect to the ground.

The noise light L3 incident on the upper surface of the light splitting member 4670 is refracted on the upper surface of the light splitting member 4670 formed with the first inclination D1. The noise light L3 refracted from the upper surface of the light splitting member 4670 travels to an area outside the profile measuring member 4650. The noise light L3 refracted on the upper surface of the light splitting member 4670 is not incident to the profile measuring member 4650.

According to the above-described exemplary embodiment of the present invention, the detecting unit 4640 is provided to the home port 460 where the laser unit 4530 waits to preemptively detect the characteristics of the laser light L required to the process treatment while the process treatment is not performed on the substrate M. Based on the detected characteristics of the laser light L, it is possible to control the characteristics of the laser light L required for efficient treatment of the substrate M by adjusting the characteristics of the laser light L. Accordingly, it is possible to efficiently perform the heat treatment on the substrate M.

In general, the data regarding the measurement distribution detected from the laser light L may only estimate the relative power value of the laser light L, and cannot be used as an index indicating the absolute power value of the laser light L. According to the example of the present invention, the focal distribution and the power of the laser light L at the home port 460 may be simultaneously measured. s In addition, by providing the profile measuring member 4650 for measuring the focal distribution of the laser light L and the power measuring member 4660 for measuring the power of the laser light L, the focal distribution and the power of the laser light L may be accurately detected and measured. Accordingly, it is possible to accurately control the characteristics of the laser light L required for performing the process by using the measured characteristics of the laser light L.

The noise light L3 reflected again from the power measuring member 4660 may not match the characteristics of the laser light L irradiated from the laser unit 4530. That is, the noise light L3 may exhibit characteristics of the laser light L distorted through reflection and refraction. According to the detecting unit 4640 according to the exemplary embodiment of the present invention, the upper and lower surfaces of the light splitting member 4670 are formed to be inclined at different angles, and the lower surface of the light splitting member 4670 is anti-reflectively coated, so that it is possible to prevent the distorted laser light L from being incident to the profile measuring member 4650 which measures the focal distribution of the laser light L. Accordingly, each of the accurate focal distribution and the power of the laser light L irradiated from the laser unit 4530 may be detected.

In the above-described exemplary embodiment of the present invention, the present invention has been described based on the case where the etch rate of the second pattern P2 is improved in the substrate M having the first pattern P1 that is the monitoring pattern for monitoring the exposure pattern and the second pattern P2 that is the pattern for setting conditions for treating the substrate as an example. However, unlike this, the functions of the first pattern P1 and the second pattern P2 may be different from those of the above-described exemplary embodiment of the present invention. In addition, according to the exemplary embodiment of the present invention, only one of the first pattern P1 and the second pattern P2 is provided, and an etch rate of the one pattern provided between the first pattern P1 and the second pattern P2 may be improved. In addition, according to the exemplary embodiment of the present invention, the same may be applied to improve an etch rate of a specific region in a substrate, such as a wafer or glass, other than a photomask.

The foregoing detailed description illustrates the present invention. Further, the above content shows and describes the exemplary embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A substrate treating apparatus, comprising:
a support unit is configured to support and rotate a substrate in a treatment space;
a liquid supply unit is configured to supply a liquid to the substrate supported by the support unit;
a laser unit including a laser irradiation unit which irradiates laser light to the substrate supported by the support unit;
a home port providing a standby position in which the laser unit waits; and
a moving unit for moving the laser unit between a process position in which the laser light is irradiated to the substrate and the standby position,
wherein the home port detects a characteristic of the laser light from the laser light irradiated by the laser unit.

2. The substrate treating apparatus of claim 1, wherein the characteristic of the laser light includes a focal distribution of the laser light and power of the laser light.

3. The substrate treating apparatus of claim 2, wherein the home port includes:
a housing having an inner space;
a profile measuring member installed in the housing and measuring the focal distribution of the laser light;
a power measuring member installed in the housing and measuring the power of the laser light; and
a light splitting member for splitting the laser light incident from an upper portion of the housing to the profile measuring member and the power measuring member.

4. The substrate treating apparatus of claim 3, wherein a surface of the light splitting member facing the power measuring member is anti-reflectively coated.

5. The substrate treating apparatus of claim 4, wherein the profile measuring member is installed on a side wall of the housing,
the power measuring member is installed on a bottom wall of the housing,
the light splitting member is disposed in the inner space of the housing,
an upper surface of the light splitting member is formed to be inclined upwardly at a first angle with respect to the ground, and a lower surface of the light splitting member is formed to be inclined upwardly at a second angle with respect to the ground, and
the second angle is greater than the first angle.

6. The substrate treating apparatus of claim 5, wherein a part of the laser light incident from the upper portion of the housing is reflected from the upper surface and is incident to the profile measuring member,
another part of the laser light incident from the upper portion of the housing is refracted on the upper surface and is incident on the lower surface, and
the laser light incident on the lower surface is incident to the power measuring member.

7. The substrate treating apparatus of claim 6, wherein a part of the laser light incident to the power measuring member is reflected and incident to the light splitting member, and the laser light incident to the light splitting member is refracted.

8. The substrate treating apparatus of claim 3, further comprising:
a lifting member installed at a lower end of the home port to move the housing.

9. The substrate treating apparatus of claim 3, wherein the profile measuring member further includes an optical filter for filtering a specific wavelength of the laser light.

10. A detecting unit for detecting a characteristic of light irradiated to a substrate, the detecting unit comprising:
a housing having an inner space;
a profile measuring member installed in the housing and measuring a focal distribution of the laser light among characteristics of the laser light;
a power measuring member installed in the housing and measuring power of the laser light among the characteristics of the laser light; and
a light splitting member for splitting the laser light incident from an upper portion of the housing to the profile measuring member and the power measuring member.

11. The detecting unit of claim 10, wherein the profile measuring member is installed on a side wall of the housing,
the power measuring member is installed on a bottom wall of the housing,
the light splitting member is disposed in the inner space of the housing, and
a surface of the light splitting member facing the power measuring member is anti-reflectively coated.

12. The detecting unit of claim 11, wherein the light splitting member has an upper surface and a lower surface each of which is formed to be inclined upwardly with respect to the ground, and
a cross-sectional area of the light splitting member increases from an upper end to a lower end of the light splitting member.

13. The detecting unit of claim 12, wherein a part of the laser light incident from the upper portion of the housing is reflected from the upper surface and is incident to the profile measuring member,
another part of the laser light incident from the upper portion of the housing is refracted on the upper surface and is incident on the lower surface, and
the laser light incident on the lower surface is incident to the power measuring member.

14. The detecting unit of claim 13, wherein a part of the laser light incident to the power measuring member is reflected and incident to the light splitting member, and the laser light incident to the light splitting member is refracted.

15. The detecting unit of claim 10, wherein the profile measuring member further includes an optical filter for filtering a specific wavelength of the laser light.

16. A substrate treating apparatus for treating a mask including a plurality of cells, the substrate treating apparatus comprising:
a housing having a treatment space;
a support unit is configured to support and rotate a mask in the treatment space;
a liquid supply unit if configured to supply a liquid to the mask supported by the support unit;
a laser unit including a laser irradiation unit which irradiates laser light to the mask supported by the support unit;
a home port providing a standby position in which the laser unit waits; and
a moving unit for moving the laser unit between a process position at which the laser light is irradiated to the mask and the standby position,
wherein the home port detects a characteristic of the laser light from the laser light irradiated by the laser unit.

17. The substrate treating apparatus of claim 16, wherein the home port includes:
a housing having an inner space;
a profile measuring member installed in the housing and measuring a focal distribution among characteristics of the laser light;
a power measuring member installed in the housing and measuring power among the characteristics of the laser light; and
a light splitting member for splitting the laser light incident from an upper portion of the housing to the profile measuring member and the power measuring member.

18. The substrate treating apparatus of claim 17, wherein the profile measuring member is installed on a side wall of the housing,
the power measuring member is installed on a bottom wall of the housing, and
the light splitting member is disposed in the inner space of the housing.

19. The substrate treating apparatus of claim 18, wherein the upper surface of the light splitting member is formed to be inclined upwardly at a first angle with respect to the ground, and the lower surface of the light splitting member is formed to be inclined upwardly at a second angle with respect to the ground,
the second angle is greater than the first angle, and
a surface of the light splitting member facing the power measuring member is anti-reflectively coated.

20. The substrate treating apparatus of claim 16, further comprising:
a lifting member installed at a lower end of the home port to move the housing,
wherein the profile measuring member further includes an optical filter for filtering a specific wavelength of the laser light.
